(19) United States
(12) Patent Application Publication
(10) Pub. No.: US 2026/0111053 A1
(43) Pub. Date: Apr. 23, 2026

(54) CLOCK SIGNAL CORRECTION DEVICE AND SEMICONDUCTOR DEVICE INCLUDING THE SAME

(71) Applicant: Samsung Electronics Co., Ltd., Suwon-si (KR)

(72) Inventors: JAEWOO JEONG, Suwon-si (KR); YONGHUN KIM, Suwon-si (KR); JINHYEOK BAEK, Suwon-si (KR); KIHO KIM, Suwon-si (KR); KIHAN KIM, Suwon-si (KR); JANG HOO KIM, Suwon-si (KR)

(21) Appl. No.: 19/248,105

(22) Filed: Jun. 24, 2025

(30) Foreign Application Priority Data
Oct. 21, 2024 (KR) 10-2024-0144115

(51) Int. Cl. G06F 1/10; G11C 7/22; H03K 5/15

(52) U.S. Cl. CPC G06F 1/10; G11C 7/222; H03K 5/15013

(57) ABSTRACT

A clock signal correction device includes a first clock signal generator configured to generate an internal clock signal in a first mode, a divider configured to generate a plurality of first clock signals having different phases based on the internal clock signal, a calibration circuit configured to generate a first skew code corresponding to a skew between a first clock signal and a second clock signal of the plurality of first clock signals and a second skew code corresponding to a skew between a third clock signal and a fourth clock signal of the plurality of first clock signals, and a skew adjustment circuit configured to adjust the phases of a plurality of second clock signals having different phases generated using a clock signal received from an external source based on the first skew code and the second skew code in a second mode different from the first mode.

### CROSS-REFERENCE TO RELATED APPLICATION(S)

This application claims priority 35 U.S.C. § 119 to and the benefit of Korean Patent Application No. 10-2024-0144115 filed at the Korean Intellectual Property Office on Oct. 21, 2024, the entire contents of which are incorporated herein by reference.

### BACKGROUND

High performance may be required for computing systems that include memory devices and memory controllers such as system on a chip (SoC). The memory controller may provide a data clock signal to the memory device separately from a clock signal for high-speed data input/output to the memory device.

On the other hand, as the data clock signal becomes faster, in order to perform stable data transmission and reception, the memory device may generate multi-phase clock signals using the data clock signal and transmit and receive data using the same. However, errors may occur during data transmission and reception due to skew between multi-phase clock signals caused by the temperature, voltage, etc. of the memory device.

### SUMMARY

An implementation of the present disclosure can provide a clock signal correction device for removing skew of a multi-phase clock signal generated by a data clock signal and a semiconductor device including the same.

A clock signal correction device according to an implementation includes a first clock signal generator configured to generate an internal clock signal in a first mode, a divider configured to generate a plurality of first multi-phase clock signals having different phases based on the internal clock signal, a calibration circuit configured to generate a first skew code corresponding to a skew between a first clock signal and a second clock signal of the plurality of first multi-phase clock signals and a second skew code corresponding to a skew between a third clock signal and a fourth clock signal of the plurality of first multi-phase clock signals, and a skew adjustment circuit configured to adjust, based on the first skew code and the second skew code, phases of a plurality of second multi-phase clock signals that have different phases, the plurality of second multi-phase clock signals being generated using a clock signal from an external source in a second mode different from the first mode.

A semiconductor device according to an implementation includes a memory controller configured to output, in a first mode, a first clock signal of a first frequency and output, in a second mode different from the first mode, a mode signal indicative of the second mode, and a memory device configured to generate, using the first clock signal in the first mode, a plurality of first multi-phase clock signals having different phases, generate, based on the mode signal, a second clock signal of a second frequency, generate a third clock signal based on a plurality of second multi-phase clock signals that have different phases, the plurality of second multi-phase clock signals being generated using the second clock signal, and determine, based on a duty cycle of the third clock signal, a value of a skew code for adjusting phases of the plurality of first multi-phase clock signals.

A computing system according to an implementation includes a memory controller configured to transmit a data clock signal and data based on a host request and transmit a mode signal indicating that a computing system has entered a first mode, and a memory device configured to: generate a clock signal based on the mode signal, generate a monitoring clock signal having a logic state that transitions in synchronization with edges of clock signals of a plurality of internal clock signals, the plurality of internal clock signals having different phases and being generated based on the clock signal, and the monitoring clock signal having a plurality of waveforms corresponding to a plurality of codes, the plurality of codes configured to adjust at least one duty cycle of the clock signals of the plurality of internal clock signals, generate, using the data clock signal, a plurality of multi-phase clock signals having different phases, and adjust phases of the plurality of multi-phase clock signals using the code that is determined based on a duty ratio of the monitoring clock signal.

### BRIEF DESCRIPTION OF THE DRAWINGS

FIG. 1 is a block diagram illustrating a computing system according to implementations of the present disclosure.

FIG. 2 is a waveform diagram showing an example of generating multi-phase clock signals.

FIG. 3 is a waveform diagram showing an example of generating multi-phase internal clock signals.

FIG. 4 is a block diagram of a computing system according to an implementation.

FIG. 5 is a block diagram of some configurations within a memory device according to an implementation.

FIG. 6 is a diagram for describing an example of operation of a calibration circuit according to an implementation.

FIG. 7 is a diagram for describing an example of operation of a calibration circuit according to an implementation.

FIG. 8 is a diagram for describing an example of operation of a calibration circuit according to an implementation.

FIG. 9 is a diagram for describing an example of operation of a calibration circuit according to an implementation.

FIG. 10 is a diagram for describing an example of operation of a calibration circuit according to an implementation.

FIG. 11 is a diagram for describing an example of operation of a calibration circuit according to an implementation.

FIG. 12 is a flowchart illustrating a clock training method according to an implementation.

FIG. 13 is a flowchart illustrating a method for a memory device to generate a skew control code according to an implementation.

FIG. 14 is an exemplary block diagram illustrating a computer system according to an implementation.

### DETAILED DESCRIPTION

Hereinafter, preferred implementations of the present disclosure will be described in detail with reference to the accompanying drawings. For identical components on a drawing, the same reference numerals are used, and duplicate descriptions of identical components are omitted.

It should be understood that the implementations described herein are intended to implement various features of the present disclosure. These are only examples and are not intended to be limiting. For example, the dimensions of the components are not limited to the disclosed ranges or values and may vary depending on process conditions and/or desired device properties. Additionally, the formation of a first structure on or above a second structure in the following description may include implementations in which the first and second structures are formed in direct contact, and may also include implementations in which additional structures may be formed between the first and second structures so that the first and second structures do not directly contact each other. For simplicity and clarity, the various structures may be drawn arbitrarily at different scales.

Spatially relative terms, such as “beneath,” “below,” “lower,” “above,” “upper” and the like, may be used herein for ease of description to describe the relationship of one element or feature to another element(s) or feature(s) as illustrated in the drawings.

The drawings and description are to be regarded as illustrative in nature and not restrictive, and like reference numerals designate like elements throughout the specification. In the flowchart described with reference to drawings in this description, the operation order may be changed, several operations may be merged, certain operations may be divided, and specific operations may not be performed.

In the description, expressions described in the singular in this specification may be interpreted as singular or plural unless an explicit expression such as “one” or “single” is used. While terms including ordinal numbers, such as “first” and “second,” etc., may be used to describe various components, such components are not limited to the above terms. These terms are only used to distinguish one component from another.

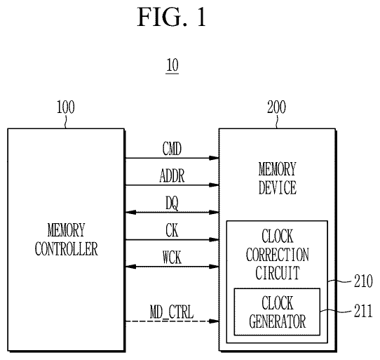

FIG. 1 is a block diagram illustrating a computing system according to implementations of the present disclosure.

Referring to FIG. 1, a computing system 10 may include a memory controller 100 and a memory device 200. The computing system 10 may be implemented to be included in a personal computer (PC) or a mobile electronic device. Mobile electronic devices may be implemented as laptop computers, mobile phones, smartphones, tablet PCs, personal digital assistants (PDAs), enterprise digital assistants (EDAs), digital still cameras, digital video cameras, portable multimedia players (PMPs), personal navigation devices (PNDs) or portable navigation devices (PNDs), handheld game consoles, mobile Internet devices (MIDs), wearable computers, Internet of Things (IoT) devices, etc.

The memory controller 100 may control the overall operation of the computing system 10 and control the overall data exchange between an external host and the memory device 200. The memory controller 100 may be implemented as an integrated circuit (IC), a system on a chip (SoC), an application processor (AP), a mobile AP, a chipset, or a collection of chips. For example, the memory controller 100 may be a semiconductor device that controls the semiconductor memory device 200 to write data or read data according to a request from a host, and the memory controller 100 may also be a component included in the application processor (AP).

In an implementation, the memory controller 100 may control the operation of the memory device 200 by applying operation commands to control the memory device 200. According to an implementation, the memory device 200 may be a dynamic random-access (DRAM), a double data rate 4 (DDR4) synchronous DRAM (SDRAM), a low-power DDR4 (LPDDR4) SDRAM, a double data rate 5 (DDR5) synchronous DRAM (SDRAM), or a low-power DDR5 (LPDDR5) SDRAM having volatile memory cells. Alternatively, the memory device 200 may be a high-bandwidth memory (HBM). On the other hand, the memory device 200 may be implemented as a nonvolatile memory device. For example, the memory device 200 may be implemented as a resistive memory such as magnetic RAM (MRAM), ferroelectric RAM (FeRAM), phase change RAM (PRAM), and resistive RAM (ReRAM). However, it is not limited thereto.

The memory controller 100 may transmit a clock signal CK, a command CMD, and an address ADDR to the memory device 200. Upon receiving the command CMD and the address ADDR from the memory controller 100 instructing the memory device 200 to write data DQ, the memory device 200 may write the data DQ to a memory location corresponding to the address ADDR. The memory controller 100 may use a data clock signal WCK when writing data DQ to the memory device 200 or reading data DQ from the memory device 200.

In an implementation, the memory device 200 may receive the data clock signal WCK from the memory controller 100 and use the data clock signal WCK to generate a plurality of clock signals having different phases (e.g., multi-phase clock signals). Here, the multi-phase clock signals are 4-phase clock signals, and may include, but are not limited to, clock signals having a phase difference of 0 degrees, 90 degrees, 180 degrees, and 270 degrees compared to the data clock signal WCK. The memory device 200 within the computing system 10 may operate using multi-phase clock signals. For example, the memory device 200 may receive data or transmit data using multi-phase clock signals having a lower frequency than the data clock signal WCK. Accordingly, the computing system 10 may perform stable data transmission and reception by transmitting and receiving data based on a multi-phase clock signal having a relatively low frequency compared to the data clock signal WCK.

Meanwhile, skew may be present in multi-phase clock signals due to various factors within the computing system 10. For example, skew may be present between multi-phase clock signals due to offsets in the clock transmission path within the memory device 200 and/or various circuits within the memory device 200. For example, 4-phase clock signals, which are multi-phase clock signals, must sequentially have a phase difference of 90 degrees, but the phase difference between the 4-phase clock signals may be greater than or less than 90 degrees due to skew. The memory device 200 according to an implementation may adjust or remove the duty and skew of multi-phase clock signals.

In an implementation, the memory device 200 may include a clock correction circuit 210. The clock correction circuit 210 may adjust or remove the duty and skew of multi-phase clock signals generated by the data clock signal WCK. The clock correction circuit 210 according to an implementation may adjust or remove the duty and skew of multi-phase clock signals generated by the data clock signal WCK based on a pre-generated skew control code. The clock correction circuit 210 according to an implementation may perform various operations to pre-generate skew control codes of multi-phase clock signals generated by the data clock signal WCK.

The memory device 200 according to an implementation may receive a mode control signal MD_CTRL from the memory controller 100. The mode control signal MD_CTRL may be, but is not limited to, a signal indicating that the computing system 10 is in initial driving (e.g., in an initial driving mode or in an initial operating mode) or a signal indicating that the memory device 200 is to enter a test mode. The memory controller 100 may also output the mode control signal MD_CTRL at regular intervals. While the memory controller 100 provides the mode control signal MD_CTRL, the memory controller 100 may not output the data clock signal WCK. In some implementations, a first-time interval during which the memory controller 100 provides the mode control signal MD_CTRL and a second time interval during which the memory controller 100 outputs the data clock signal WCK during a plurality of times during which the computing system 10 operates may not overlap each other.

In an implementation, the clock correction circuit 210 may include a clock generator 211. The clock generator 211 according to an implementation may generate an internal clock signal during initial driving of the computing system 10 or during a predetermined time interval. The clock generator 211 according to an implementation may generate an internal clock signal based on the mode control signal MD_CTRL received from the memory controller 100. Here, the frequency of the internal clock signal may be substantially the same as the data clock signal WCK, but is not limited thereto. Additionally, the clock generator 211 may be an oscillator, and the internal clock signal may include, but is not limited to, an oscillation signal generated by the oscillator.

In an implementation, the clock correction circuit 210 may generate a plurality of clock signals having different phases (hereinafter referred to as multi-phase internal clock signals) using an internal clock signal generated by the clock generator 211, and perform duty adjustment and skew adjustment operations on each of the multi-phase internal clock signals. Specifically, the clock correction circuit 210 may generate multi-phase internal clock signals using an internal clock signal generated by the clock generator 211. The clock correction circuit 210 may generate a clock signal (hereinafter referred to as a monitoring clock signal) in synchronization with the rising edge of multi-phase internal clock signals. The clock correction circuit 210 may monitor the duty of the monitoring clock signal according to the skew code and determine the skew code to set the duty ratio of the monitoring clock signal to substantially 50%. The clock correction circuit 210 may determine a skew control code as the final skew code based on the determined skew code. In an implementation, the memory device 200 may adjust or control the duty and skew of the data clock signal WCK and multi-phase clock signals generated using the data clock signal WCK, using a predetermined skew control code. Accordingly, data transmission and reception operation characteristics using multi-phase clock signals may be improved.

According to an implementation, the memory device 200 may generate an internal clock signal during initial driving when the memory controller 100 does not provide the data clock signal WCK or during a predetermined time interval, and use the internal clock signal to generate a skew control code. The memory device 200 according to an implementation may reduce training time by adjusting or removing the duty and skew of multi-phase clock signals generated by the data clock signal WCK using a pre-generated skew control code, and has an advantage in that the skew of multi-phase clock signals may be corrected in an environment in which the product is actually used—i.e., an implementation environment.

On the other hand, for convenience of description, it is stated herein that the memory device 200 generates multi-phase clock signals using the data clock signal WCK received from the memory controller 100, and the clock correction circuit 210 may adjust or remove the duty and skew of the multi-phase clock signals generated using the data clock signal WCK, but is not limited thereto. For example, the clock correction circuit 210 of the memory device 200 may adjust or remove the duty and skew of multi-phase clock signals generated by a strobe signal DQS and/or the clock signal CLK received from the memory controller 100.

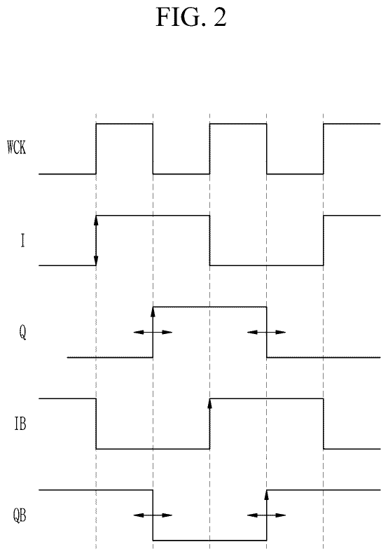

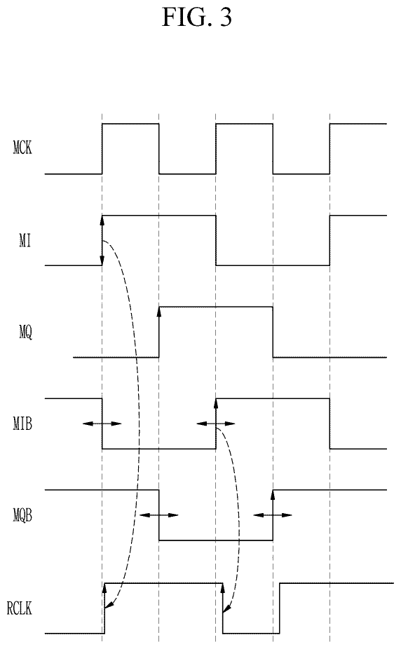

FIGS. 2 and 3 are waveform diagrams showing examples of generating multi-phase internal clock signals. Hereinafter, it is assumed that the multi-phase clock signals sequentially include first to fourth clock signals having a phase difference of 90 degrees.

Referring to FIG. 2, the memory device (200 of FIG. 1) may receive the data clock signal WCK from the memory controller (100 of FIG. 1) and generate 4-phase clock signals based on the data clock signal WCK. The 4-phase clock signals may include first to fourth clock signals having a phase difference of 0 degrees, 90 degrees, 180 degrees, and 270 degrees relative to the data clock signal WCK.

The 4-phase clock signals may include first through fourth clock signals I, Q, IB, and QB. In an exemplary implementation, the first to fourth clock signals I, Q, IB, and QB may have a frequency that is half that of the data clock signal WCK and may be generated in synchronization with a rising edge and a falling edge of the data clock signal WCK. For example, the first clock signal I may be generated in synchronization with the first rising edge of the data clock signal WCK, the second clock signal Q may be generated in synchronization with the first falling edge of the data clock signal WCK, the third clock signal IB may be generated in synchronization with the second rising edge of the data clock signal WCK, and the fourth clock signal QB may be generated in synchronization with the second falling edge of the data clock signal WCK.

On the other hand, skew may be present in the first to fourth clock signals I, Q, IB, and QB due to various factors in the computing system. When monitoring the duty of the data clock signal WCK, the skew for a 90-degree phase difference between the first clock signal I and the second clock signal Q and the skew for a 90-degree phase difference between the third clock signal IB and the fourth clock signal QB may be detected. However, the skew for a 180-degree phase difference between the first clock signal I and the third clock signal (IB) and the skew for a 180-degree phase difference between the second clock signal Q and the fourth clock signal QB cannot be detected by duty monitoring of the data clock signal WCK.

Referring to FIG. 3, the clock generator (211 of FIG. 1) of the memory device (200 of FIG. 1) may generate an internal clock signal MCK. Here, the frequency of the internal clock signal MCK may be substantially the same as the frequency of the data clock signal WCK, but is not limited thereto. The clock correction circuit (210 of FIG. 1) of the memory device 200 may generate 4-phase signals based on the internal clock signal MCK. The 4-phase signals may include first to fourth internal clock signals having a phase difference of 0 degrees, 90 degrees, 180 degrees, and 270 degrees relative to the internal clock signal MCK.

The 4-phase internal clock signals may include first to fourth internal clock signals MI, MQ, MIB, and MQB. In an exemplary implementation, the first to fourth internal clock signals MI, MQ, MIB, and MQB may have a frequency that is half that of the internal clock signal MCK and may be generated in synchronization with the rising edge and falling edge of the internal clock signal MCK.

According to an implementation, the memory device (200 of FIG. 1) may perform multiple steps during initial driving of the computing system (10 of FIG. 1) or during a predetermined time interval, and generate a monitoring clock signal RCLK in synchronization with the rising edges of the first internal clock signal MI and the third internal clock signal MIB. In an implementation, the memory device 200 may detect skew for a 180-degree phase difference between the first internal clock signal MI and the third internal clock signal MIB through duty monitoring for the monitoring clock signal RCLK. This operation may also be performed for the second internal clock signal MQ and the fourth internal clock signal MQB. In an implementation, the memory device 200 may generate a skew control code to adjust the skew so that the first to fourth internal clock signals MI, MQ, MIB, and MQB sequentially have a phase difference of 90 degrees. The memory device 200 may adjust the phase difference of 4-phase clock signals I, Q, IB, and QB generated by the data clock signal WCK to 90 degrees based on a skew control code. Below, a method for generating a skew control code of the memory device 200 is described in detail.

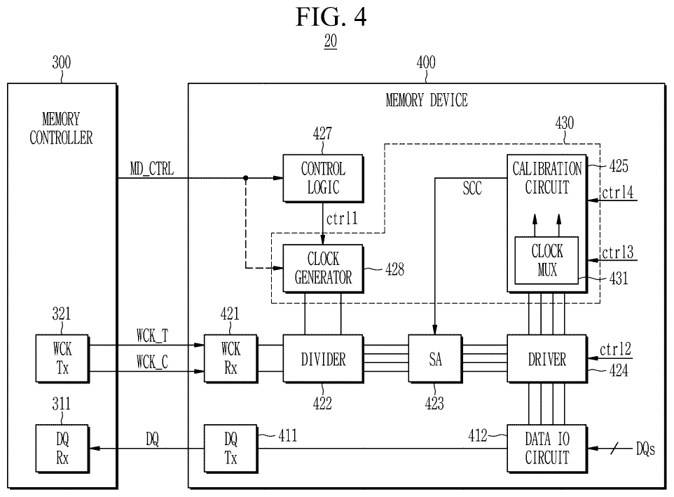

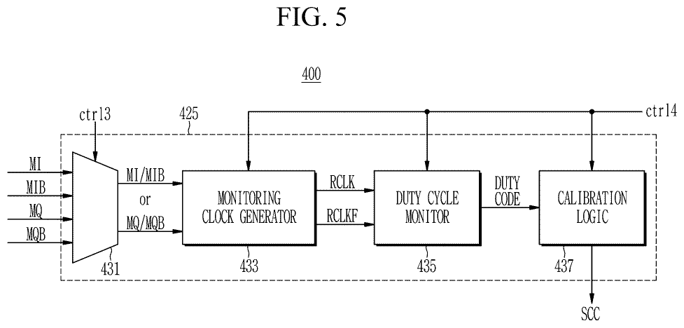

FIG. 4 is a block diagram of a computing system according to an implementation, and FIG. 5 is a block diagram of some configurations within a memory device according to an implementation.

Referring to FIG. 4, a computing system 20 may include a memory controller 300 and a memory device 400. The memory device 400 may include a data transmitter 411, a data input/output circuit (data I/O circuit) 412, a data clock signal receiver 421, a divider 422, a skew adjuster 423 (also referred to as a skew adjustment circuit), a driver 424, a control logic 427, and a clock correction circuit 430. The clock correction circuit 430 according to an implementation may include a calibration circuit 425 and a clock generator 428.

The memory controller 300 may include a data receiver 311 and a data clock signal transmitter 321. The data transmitter 411 may provide data DQ to the memory controller 300 through a data channel. Additionally, the data clock signal receiver 421 may receive the data clock signal WCK. The data clock signal WCK may include differential signals WCK_T and WCK_C.

In an implementation, the data clock signal receiver 421 may receive the data clock signal WCK from an external source (e.g., the memory controller 300), when the computing system 10 is in an operation mode (e.g., for reading, writing, or erasing a data). The divider 422 may generate multi-phase clock signals using the data clock signal WCK. For example, the divider 422 may sequentially generate first to fourth clock signals I, IB, Q, and QB having a phase difference of 90 degrees using the data clock signal WCK.

The skew adjuster 423 according to an implementation may receive a skew control code SCC from the calibration circuit 425. The skew control code SCC may include a first skew control code for adjusting the skew of at least one of the first clock signal I and the third clock signal IB, and a second skew control code for adjusting the skew of at least one of the second clock signal Q and the fourth clock signal QB. The skew controller 423 may receive the first to fourth clock signals I, IB, Q, and QB from the divider 422 and adjust the duty and skew of the first to fourth clock signals I, IB, Q, and QB based on the skew control code SCC. The skew adjuster 423 may receive the first to fourth clock signals I, IB, Q, and QB from the divider 422 and adjust the phases of the first to fourth clock signals I, IB, Q, and QB based on the skew control code SCC.

The driver 424 may drive and output the first to fourth clock signals I, IB, Q, and QB with adjusted skew based on a second control signal ctrl2. For example, the driver 424 may transmit the first to fourth clock signals I, IB, Q, and QB received from the skew adjuster 423 to the data input/output circuit 412 based on the second control signal ctrl2. The data input/output circuit 412 may provide read data DQ to the memory controller 300 through the data transmitter 411 in synchronization with the first to fourth clock signals I, IB, Q, and QB with adjusted skew.

In an implementation, the control logic 427 of the memory device 400 may receive the mode control signal MD_CTRL from the memory controller 300. The mode control signal MD_CTRL may be, but is not limited to, a signal indicating that the computer system 20 is in initial driving mode or a signal indicating that the memory device 400 has entered a test mode. Additionally, the memory device 400 may periodically receive the mode control signal MD_CTRL from the memory controller 300. The control logic 427 may output control signals ctrl1, . . . ctrl4 for controlling components in the memory device 400 based on the mode control signal MD_CTRL. In an implementation, while the memory controller 300 outputs the mode control signal MD_CTRL, the memory controller 300 may not output the data clock signal WCK. According to an implementation, while not receiving the data clock signal WCK from the memory controller 300, the memory device 400 may perform a training operation for skew control of multi-phase clock signals.

In an implementation, the clock generator 428 may receive a first control signal ctrl1 from the control logic 427. The clock generator 428 may generate the internal clock signal MCK having a waveform similar to that of the internal clock signal MCK of FIG. 3 based on the first control signal ctrl1. According to an implementation, the frequency of the internal clock signal MCK may be substantially equal to the frequency of the data clock signal WCK. However, it is not limited thereto. Meanwhile, although it is stated here that the clock generator 428 receives the first control signal ctrl1 from the control logic 427 and generates the internal clock signal MCK based thereon, the clock generator 428 may also receive the mode control signal MD_CTRL directly from the memory controller 300 and generate the internal clock signal MCK based thereon.

In an implementation, the divider 422 may receive the internal clock signal MCK and use the internal clock signal MCK to generate multi-phase internal clock signals having different phases. For example, the divider 422 may sequentially generate the first to fourth internal clock signals MI, MIB, MQ, and MQB having a phase difference of 90 degrees using the internal clock signal MCK.

In an implementation, the first to fourth internal clock signals MI, MIB, MQ, and MQB may be transmitted to the driver 424 via the skew adjuster 423. The driver 424 may output the first to fourth internal clock signals MI, MIB, MQ, and MQB based on the second control signal ctrl2 received from the control logic 427. For example, the driver 424 may transmit the first to fourth internal clock signals MI, MIB, MQ, and MQB received from the skew adjuster 423 to the calibration circuit 425 based on the second control signal ctrl2.

In an implementation, the calibration circuit 425 may receive a fourth control signal ctrl4 instructing to perform a calibration operation, and may perform various operations to generate the skew control code SCC using the first to fourth internal clock signals MI, MIB, MQ, and MQB. Specifically, the clock multiplexer 431 in the calibration circuit 425 may receive the first to fourth internal clock signals MI, MIB, MQ, and MQB, select two internal clock signals having a phase difference of 180 degrees based on a third control signal ctrl3. For example, the clock multiplexer 431 may output the first and third internal clock signal MI, MIB based on the third control signal ctrl 3 having a first value(e.g., logic high), or output the second and forth internal clock signal MQ, MQB based on the third control signal ctrl 3 having a second value(e.g., logic low). The calibration circuit 425 may perform operations to output skew control code SCC based on the internal clock signals output from the clock multiplexer 431. For example, the calibration circuit 425 may generate a monitoring clock signal synchronized to the rising edge of the internal clock signals, and generate the skew control code SCC based on a duty cycle of the monitoring clock signal. The calibration circuit 425 may output the skew control code SCC to the skew adjuster 423. This will be described later with reference to FIG. 5 to FIG. 13.

FIG. 5 is a block diagram of some configurations within a memory device according to an implementation. Specifically, it's a block diagram of the calibration circuit 425 in the memory device 400.

In an implementation, calibration circuit 425 may include a clock multiplexer 431, a monitoring clock generator 433, a duty cycle monitor 435, and calibration logic 437.

As described above with reference to FIG. 4, the clock multiplexer 431 may receive the first to fourth internal clock signals MI, MIB, MQ, MQB and select two internal clock signals having a phase difference of 180 degrees based on a third control signal ctrl3 received from the control logic 427. For example, the clock multiplexer 431 may output the first and third internal clock signals MI, MIB based on the third control signal ctrl3 having a first value(logic high), or the second and fourth internal clock signals MQ, MQB based on the third control signal ctrl3 having a second value(logic low).

In an implementation, the monitoring clock generator 433 may receive the first and third internal clock signals MI, MIB or the second and fourth internal clock signals MQ, MQB from the clock multiplexer 431 and output a signal synchronized to the rising edges of the first and third internal clock signals MI, MIB or the second and fourth internal clock signals MQ, MQB as a monitoring clock signal RCLK.

In an implementation, the monitoring clock generator 433 may generate the monitoring clock signal RCLK synchronously to the rising edges of the first internal clock signal MI and the third internal clock signal MIB, and output the monitoring clock signal RCLK. For example, the monitoring clock generator 433 may receive the first and third internal clock signals MI, MIB from the clock multiplexer 431, and output the monitoring clock signal RCLK transitioning to a first logic state (e.g., high state) at an edge (e.g., rising edge) timing of the first internal clock signal MI and transitioning to a second logic state (e.g., low state) at an edge (rising edge) timing of the third internal clock signal MIB.

In an implementation, the duty cycle monitor 435 may receive the monitoring clock signal RCLK and perform a duty monitoring operation on the monitoring clock signal RCLK. Specifically, the duty cycle monitor 435 may output a monitoring result according to the duty ratio of the monitoring clock signal RCLK as a duty code based on the monitoring clock signal RCLK with adjusted duty according to the skew code. At this time, the value of the skew code may sequentially increase from a minimum value (e.g., −7) to a maximum value (e.g., +7), but is not limited thereto. The duty cycle monitor 435 may output the first value (e.g., logic low) as a duty code when the duty ratio of the monitoring clock signal RCLK according to the skew code is less than 50 (i.e., the logic low period is longer), and may output the second value (e.g., logic high) as a duty code when the duty ratio of the monitoring clock signal RCLK is 50 or more (i.e., the logic high period is longer).

In an implementation, the calibration logic 437 may receive a skew code and a corresponding duty code from the duty cycle monitor 435, and output a skew control code for adjusting the skew of at least one of the first internal clock signal MI and the third internal clock signal MIB based thereon.

In an implementation, the monitoring clock generator 433 may generate a flipped monitoring clock signal RCLKF in synchronization with the rising edges of the first internal clock signal MI and the third internal clock signal MIB. For example, the monitoring clock generator 433 may receive the first and third internal clock signals MI and MIB from the clock multiplexer 431, and generate the flipped monitoring clock signal RCLKF that transitions to the first logic state (high state) at an edge (rising edge) timing of the third internal clock signal MIB, and transitions to the second logic state (low state) at an edge (rising edge) timing of the first internal clock signal MI.

In an implementation, the duty cycle monitor 435 may perform a duty monitoring operation for the flipped monitoring clock signal RCLKF. The duty monitoring operation of the duty cycle monitor 435 for the flipped monitoring clock signal RCLKF is similar or identical to the duty monitoring operation for the monitoring clock signal RCLK.

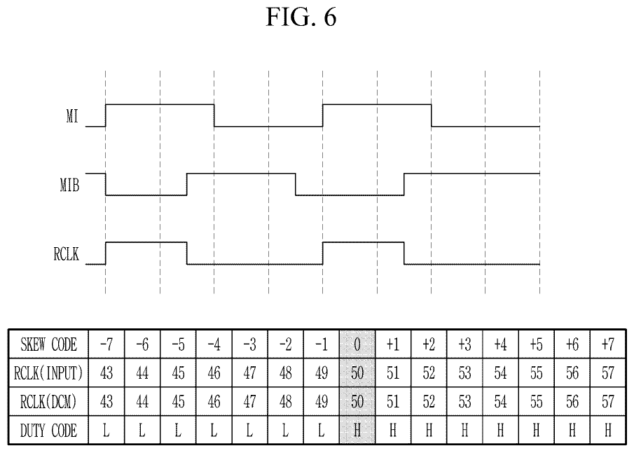

FIGS. 6 to 8 are diagrams for describing an example of operation of a calibration circuit according to an implementation.

The calibration circuit 425 according to an implementation may generate a duty code for the monitoring clock signal RCLK to remove skew between the first internal clock signal MI and the third internal clock signal MIB. At this time, the calibration circuit 425 may further generate the flipped monitoring clock signal RCLKF to remove an offset in the duty cycle monitor 435, and the duty cycle monitor 435 may perform a duty monitoring operation on the monitoring clock signal RCLK and on the flipped monitoring clock signal RCLKF. FIGS. 6 to 8 describe the operation method of the duty cycle monitor 435 when there is no offset. Meanwhile, offset may be a slight timing difference caused by physical characteristics of the duty cycle monitor 435.

As shown in FIG. 6, the monitoring clock signal RCLK may be generated in synchronization with the rising edges of the first internal clock signal MI and the third internal clock signal MIB. Specifically, the monitoring clock signal RCLK transitions to logic high at the rising edge timing of the first internal clock signal MI and transitions to logic low at the rising edge timing of the third internal clock signal MIB. Looking at the table in FIG. 6, as the skew code changes by “1,” the duty ratio of a monitoring clock signal RCLK (INPUT) input to the duty cycle monitor 435 changes by 1%. However, this is only an example and is not limited thereto. On the other hand, since it is assumed that there is no offset of the duty cycle monitor 435, the duty ratio of the monitoring clock signal RCLK (INPUT) input to the duty cycle monitor 435 and the duty ratio of a monitoring clock signal RCLK (DCM) determined by the duty cycle monitor 435 are the same. Specifically, the duty cycle monitor 435 may perform a duty monitoring operation for the monitoring clock signal RCLK (DCM) determined by the duty cycle monitor 435 while increasing a skew code. The duty cycle monitor 435 may determine that the monitoring clock signal RCLK (DCM) has a waveform with a relatively long logic high period when the duty ratio of a monitoring clock signal RCLK (DCM) is longer than or equal to 50. Referring to the table in FIG. 6, the duty cycle monitor 435 determined that the monitoring clock signal RCLK (DCM) has a waveform with a relatively long logic high period when the skew code has a value of “0.” That is, the duty cycle monitor 435 outputs logic high (“H”) as the duty code when the skew code has a value of “0”.

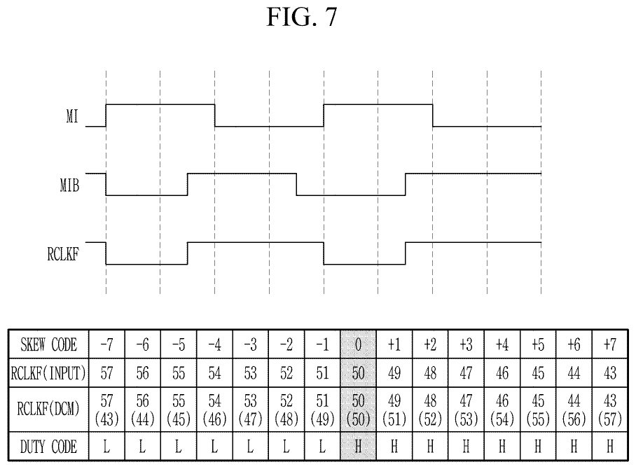

Referring to FIG. 7, the flipped monitoring signal RCLKF may be generated in synchronization with the rising edges of the first internal clock signal MI and the third internal clock signal MIB. Specifically, the flipped monitoring signal RCLK transitions to logic low at the rising edge timing of the first internal clock signal MI and transitions to logic high at the rising edge timing of the third internal clock signal MIB. Looking at the table in FIG. 7, the duty ratio of a flipped monitoring clock signal RCLKF (INPUT) input to the duty cycle monitor 435 is shown to change by 1% as the skew code changes by 1%, but is not limited thereto. Since it is assumed that there is no offset of the duty cycle monitor 435, the duty ratio of the flipped monitoring clock signal RCLKF (INPUT) input to the duty cycle monitor 435 and the duty ratio of the flipped monitoring clock signal RCLKF (DCM) determined by the duty cycle monitor 435 are the same. Meanwhile, since the duty cycle monitor 435 receives the flipped signal as an input signal, the duty cycle monitor 435 determines the duty ratio based on a signal that is an inverted version of the flipped monitoring clock signal RCLKF (DCM). For example, if the duty ratio of the flipped monitoring clock signal RCLKF (DCM) is 57%, the duty code is determined based on the duty ratio of 43% of the signal that is an inverted version of the flipped monitoring clock signal RCLKF (DCM). Referring to FIG. 7, the duty cycle monitor 435 determines that when the skew code has a value of “0,” the inverted signal of the flipped monitoring clock signal RCLKF (DCM) has a waveform with a relatively long logic high period. That is, the duty cycle monitor 435 outputs logic high (“H”) as the duty code when the skew code has a value of “0.”

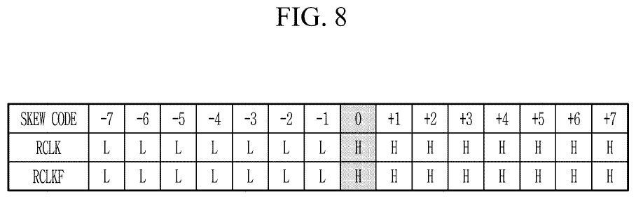

FIG. 8 shows the results according to the duty monitoring operation in FIGS. 6 and 7.

Referring to FIG. 8, the duty monitoring results using the monitoring clock signal RCLK and the flipped monitoring clock signal RCLKF are illustrated. The duty cycle monitor 435 may output a duty code as a monitoring result based on the waveforms of the monitoring clock signal RCLK and the flipped monitoring clock signal RCLKF.

In an implementation, the calibration logic (437 of FIG. 5) may output a skew control code to remove skew between the first internal clock signal MI and the third internal clock signal MIB based on the duty code. Referring to FIG. 8, the calibration logic 437 may determine a skew code (“0”) in which duty is changed from logic low (“L”) to logic high (“H”) according to the waveform of the monitoring clock signal RCLK and a skew code (“0”) in which duty is changed from logic low (“L”) to logic high (“H”) according to the waveform of the flipped monitoring clock signal RCLKF, and may transmit the intermediate value, a skew code (“0”), to the skew adjuster (423 of FIG. 5) as the final skew control code SCC. That is, FIG. 8 corresponds to a monitoring result in the case in which there is no skew between the first internal clock signal MI and the third internal clock signal MIB, and the first skew control code for adjusting the skew between the first internal clock signal MI and the third internal clock signal MIB may be determined as “0.”

The operations of FIGS. 6 and 7 described above may be repeatedly performed on the second internal clock signal MQ and the fourth internal clock signal MQB.

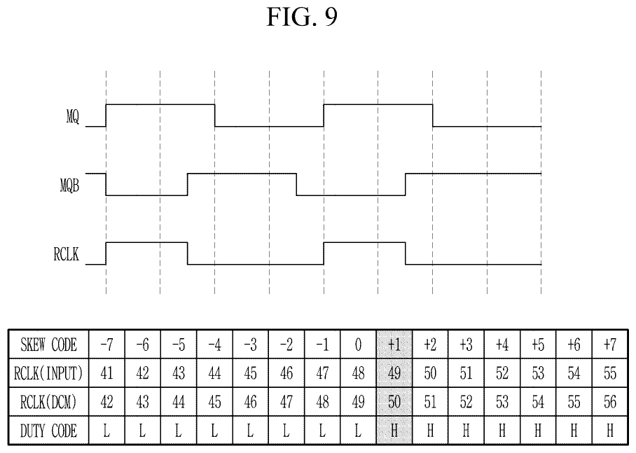

FIGS. 9 to 11 are drawings for describing an example of operation of a calibration circuit according to an implementation.

The calibration circuit 425 according to an implementation may generate a duty code for the monitoring clock signal RCLK to remove skew between the first internal clock signal MI and the third internal clock signal MIB. At this time, the calibration circuit 425 may further generate the flipped monitoring clock signal RCLKF to remove an offset within the duty cycle monitor 435, and the duty cycle monitor 435 may perform a duty monitoring operation on the monitoring clock signal RCLK and on the flipped monitoring clock signal RCLKF. FIGS. 9 to 11 describe the operation method of the duty cycle monitor 435 when an offset of the duty cycle monitor 435 is present. Here, descriptions identical or similar to those in FIGS. 6 to 8 are omitted.

Referring to FIG. 9, the monitoring clock signal RCLK may be generated in synchronization with the rising edges of the second internal clock signal MQ and the fourth internal clock signal MQB. Specifically, the monitoring clock signal RCLK transitions to logic high at the rising edge timing of the second internal clock signal MQ and transitions to logic low at the rising edge timing of the fourth internal clock signal MQB. Referring to the table in FIG. 9, the duty ratio of the monitoring clock signal RCLK (INPUT) input to the duty cycle monitor 435 and the duty ratio of the monitoring clock signal RCLK (DCM) determined by the duty cycle monitor 435 are different due to the offset of the duty cycle monitor 435. The duty cycle monitor 435 generates a duty code based on the monitoring clock signal RCLK (DCM) determined by the duty cycle monitor 435, so that the duty cycle monitor 435 outputs a logic high (“H”) as the duty code when the skew code has a value of “+1.”

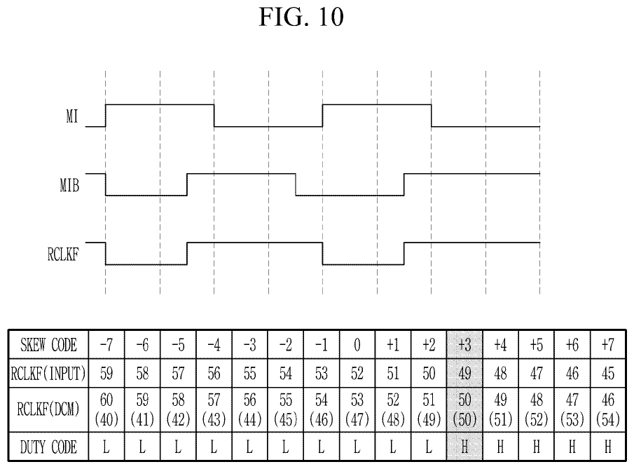

Referring to FIG. 10, the flipped monitoring signal RCLKF may be generated in synchronization with the rising edges of the second internal clock signal MB and the fourth internal clock signal MQB. Specifically, the flipped monitoring signal RCLK transitions to logic low at the rising edge timing of the second internal clock signal MQ and transitions to logic high at the rising edge timing of the fourth internal clock signal MQB. Referring to the table in FIG. 10, since the duty cycle monitor 435 receives a flipped signal as an input signal, the duty cycle monitor 435 determines the duty ratio based on a signal that is an inverted version of the flipped monitoring clock signal RCLKF (DCM). For example, if the duty ratio of the flipped monitoring clock signal RCLKF (DCM) is 58%, the duty code is determined based on the duty ratio of 42% of the signal that is an inverted version of the flipped monitoring clock signal RCLKF (DCM). Meanwhile, since there is an offset in the duty cycle monitor 435, the duty ratio of the flipped monitoring clock signal RCLKF (INPUT) input to the duty cycle monitor 435 and the duty ratio of the flipped monitoring clock signal RCLKF (DCM) determined by the duty cycle monitor 435 are different. Referring to FIG. 10, the duty cycle monitor 435 determines that the flipped monitoring clock signal RCLKF (DCM) has a waveform with a relatively long logic high period when the skew code has a value of “+3.” That is, the duty cycle monitor 435 outputs logic high (“H”) as the duty code when the skew code has a value of “+3.”

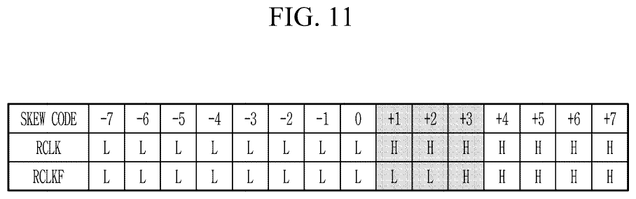

FIG. 11 shows the results according to the duty monitoring operation in FIGS. 9 and 10.

Referring to FIG. 11 with FIG. 9 and FIG. 10, the calibration logic 437 determines a skew code (“+1”) in which duty is changed from logic low (“L”) to logic high (“H”) according to the monitoring clock signal RCLK and a skew code (“+3”) in which duty is changed from logic low (“L”) to logic high (“H”) according to the flipped monitoring clock signal RCLKF, and may transmit a skew code (“+2”), which is an intermediate value (or an average value) of these, to the skew adjuster 423 as the final skew control code SCC. That is, the second skew control code for adjusting the skew between the second internal clock signal MQ and the fourth internal clock signal MQB may be determined as “+2.”

As described above, the monitoring clock signal generation and duty monitoring operations on the first and third internal clock signals MI and MIB and on the second and fourth internal clock signals MQ and MQB may be performed, and the first skew control code and the second skew control code may be transmitted to the skew adjuster 423 as skew control codes SCC.

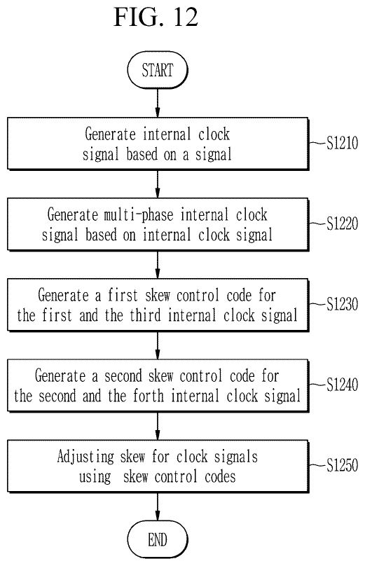

FIG. 12 is a flowchart illustrating a clock training method according to an implementation.

In an implementation, the memory device 400 may generate an internal clock signal based on a signal (S1210). For example, the signal may be a signal transmitted from outside or inside the memory device 400, and the signal may be a signal indicating that a computing system including the memory device 400 is in an initial driving mode, or a signal indicating that the memory device 400 is to enter a test mode. While the signal is being transmitted, the memory device 400 may not receive the data clock signal WCK.

In an implementation, the memory device 400 may generate a multi-phase internal clock signal based on an internal clock signal (S1220). Specifically, the memory device 400 may generate first to fourth internal clock signals having a phase difference of 0 degrees, 90 degrees, 180 degrees, and 270 degrees with respect to the internal clock signal, and use the same to generate a skew control code.

In an implementation, the memory device 400 may generate a first skew control code for the first and third internal clock signals having a phase difference of 180 degrees (S1230) and generate a second skew control code for second and fourth internal clock signals having a phase difference of 180 degrees (S1240).

In an implementation, the memory device 400 may adjust skew for multi-phase clock signals generated based on the data clock signal WCK using the first skew control code and a second skew control code (S1250).

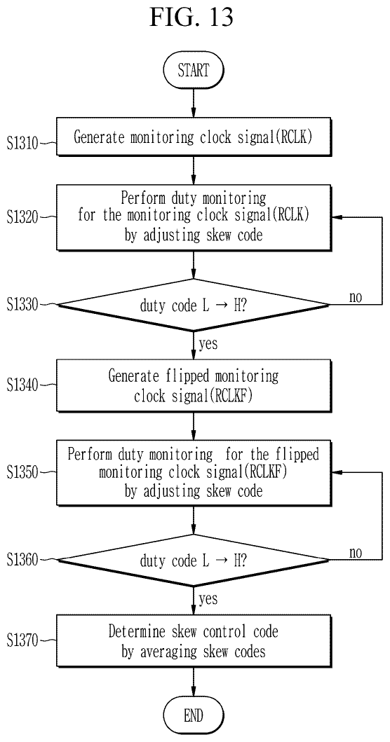

FIG. 13 is a flowchart illustrating a method for a memory device to generate a skew control code according to an implementation. Specifically, as a specific method for steps (S1230 and S1240), each step of FIG. 13 may be performed for the first and third internal clock signals and the second and fourth internal clock signals having a phase difference of 180 degrees.

In an implementation, the memory device 400 may generate the monitoring clock signal RCLK (S1310). The memory device 400 according to an implementation may generate the monitoring clock signal RCLK based on the first and third internal clock signals or the second and fourth internal clock signals. For example, the monitoring clock signal RCLK may transition to logic high on the rising edge of the first internal clock signal MI and transition to logic low on the rising edge of the third internal clock signal MIB. Alternatively, the monitoring clock signal RCLK may transition to logic high on the rising edge of the second internal clock signal MQ and transition to logic low on the rising edge of the fourth internal clock signal MQB. In an implementation, the memory device 400 may perform duty monitoring for the monitoring clock signal RCLK while adjusting the skew code (S1320). Specifically, the memory device 400 may output a monitoring result as a duty code according to the duty ratio of the monitoring clock signal RCLK having a different waveform depending on a skew code. In other words, the waveform of the monitoring clock signal RCLK can be adjusted based on a corresponding skew code. Therefore, the memory device 400 can generate, based on a plurality of skew codes, a plurality of monitoring clock signals with a plurality of waveforms. Each waveform is based on a respective skew code. For each waveform, the memory device 400 can determine a duty ratio of the monitoring clock signal RCLK. The memory device 400 can then determine, based on the determined duty ratio, a duty code associated with the respective skew code. Therefore, the memory device 400 can determine a plurality of duty codes that are respectively associated with the plurality of skew codes. Additionally, as noted above, both monitoring clock signals RCLK and flipped monitoring clock signals RCLKF can be generated based on the clock signals. The plurality of monitoring clock signals (and/or the plurality of flipped monitoring clock signals RCLKF) that are generated based on the first and third clock signals may be referred to as a first set of monitoring clock signals, while the plurality of monitoring clock signals (and/or the plurality of flipped monitoring clock signals RCLKF) that are generated based on the second and fourth clock signals may be referred to as a second set of monitoring clock signals in the present disclosure. In some examples, if the waveform of the monitoring clock signal RCLK has a relatively long logic low period, a logic low (“L”) value may be output as the duty code, and if the waveform of the monitoring clock signal RCLK has a relatively long logic high period, a logic high (“H”) value may be output as the duty code.

In an implementation, the memory device 400 may determine the skew code of the period in which the duty code changes from logic low (“L”) to logic high (“H”) (S1330). At this time, the memory device 400 generates the monitoring clock signal RCLK according to all skew codes and performs duty monitoring for the monitoring clock signal RCLK, thereby determining the skew code of the period in which the duty code changes. Alternatively, the memory device 400 determines whether the duty code changes from logic low (“L”) to logic high (“H”) for each period of the monitoring clock signal RCLK corresponding to each skew code, and if the period in which the duty code of the monitoring clock signal RCLK changes from logic low (“L”) to logic high (“H”) is determined, the memory device 400 may perform the next step without generating any more monitoring clock signals RCLK. The memory device 400 according to an implementation may store a skew code in a period in which a duty code changes from logic low (“L”) to logic high (“H”) as a first skew code.

In an implementation, the memory device 400 may generate the flipped monitoring clock signal RCLKF (S1340). The memory device 400 according to an implementation may generate the flipped monitoring clock signal RCLKF based on the first and third internal clock signals or the second and fourth internal clock signals. For example, the flipped monitoring clock signal RCLKF may transition to logic low on the rising edge of the first internal clock signal MI and transition to logic high on the rising edge of the third internal clock signal MIB. Alternatively, the flipped monitoring clock signal RCLKF may transition to logic low on the rising edge of the second internal clock signal MQ and transition to logic high on the rising edge of the fourth internal clock signal MQB.

In an implementation, the memory device 400 may perform duty monitoring for the flipped monitoring clock signal RCLKF while adjusting the skew code (S1350). At this time, the memory device 400 may generate a duty cycle monitoring result for the inverted value of the flipped monitoring clock signal RCLKF as a duty code. For example, when the waveform of the flipped monitoring clock signal RCLKF has a relatively long logic low period, a logic high (“H”) value may be output as a duty code according to the inverted value of the flipped monitoring clock signal RCLKF, and when the waveform of the flipped monitoring clock signal RCLKF has a relatively long logic high period, a logic low (“L”) value may be output as a duty code according to the inverted value of the flipped monitoring clock signal RCLKF. The memory device 400 according to an implementation may store a skew code in a period in which a duty code changes from logic low (“L”) to logic high (“H”) as a second skew code.

The memory device according to an implementation may determine a skew code, which is an intermediate value (or average value) of the first skew code and the second skew code, as a skew control code, which is the final skew code (S1370).

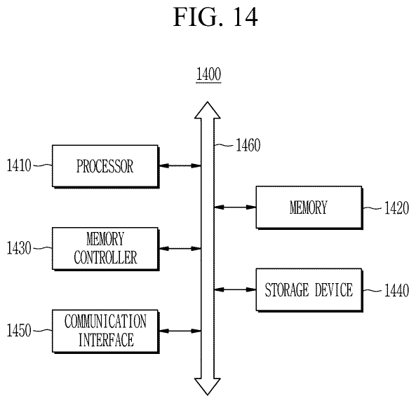

FIG. 14 is an example block diagram illustrating a computer system according to an implementation.

Referring to FIG. 14, a computing system 1400 includes a processor 1410, a memory 1420, a memory controller 1430, a storage device 1440, a communication interface 1450, and a bus 1460. The computing system 1400 may further include other general-purpose components.

The processor 1410 controls the overall operation of each component of the computing system 1400. The processor 1410 may be implemented as at least one of various processing units such as a central processing unit (CPU), an application processor (AP), and a graphic processing unit (GPU).

The memory controller 1430 controls the transfer of data or instructions to and from the memory 1420. The memory controller 1430 may be provided as an internal configuration of the processor 1410. In some implementations, the memory controller 1430 may be provided as a separate chip from the processor 1410. The memory controller 1430 may transmit data DQ to the memory 1420 together with a data clock signal WCK. In an implementation, the memory controller 1430 may transmit a signal to the memory 1420 indicating that the computing system 1400 is starting up or that the memory 1420 is entering a test state.

The memory 1420 stores various data and instructions. The memory 1420 may be implemented as a memory device described with reference to FIGS. 1 to 13. The memory 1420 may generate an internal clock signal based on a signal received from the memory controller 1430 and perform a training operation on the multi-phase internal clock signal generated based thereon. The memory 1420 may generate a skew control code as a training result for the multi-phase internal clock signal, and adjust and remove the duty and skew of the multi-phase clock signals generated based on the data clock signal WCK based on the skew control code.

The storage device 1440 permanently stores programs and data. In some implementations, the storage device 1440 may be implemented as non-volatile memory. The communication interface 1450 supports wired and wireless Internet communication of the computing system 1400. Additionally, the communication interface 1450 may support various communication methods other than Internet communication. The bus 1460 provides communication between components of the computing system 1400. The bus 1460 may include at least one type of bus depending on the communication protocol between the components.

In some implementations, each component or combination of two or more components described with reference to FIGS. 1 to 13 may be implemented as a digital circuit, a programmable or non-programmable logic device or array, an application-specific integrated circuit (ASIC), or the like.

While this disclosure contains many specific implementation details, these should not be construed as limitations on the scope of what may be claimed. Certain features that are described in this disclosure in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

What is claimed is:

1. A clock signal correction device comprising:
a first clock signal generator configured to generate an internal clock signal in a first mode;
a divider configured to generate a plurality of first multi-phase clock signals having different phases based on the internal clock signal;
a calibration circuit configured to generate a first skew code corresponding to a skew between a first clock signal and a second clock signal of the plurality of first multi-phase clock signals and a second skew code corresponding to a skew between a third clock signal and a fourth clock signal of the plurality of first multi-phase clock signals; and
a skew adjustment circuit configured to adjust, based on the first skew code and the second skew code, phases of a plurality of second multi-phase clock signals that have different phases, the plurality of second multi-phase clock signals being generated using a clock signal from an external source in a second mode different from the first mode.

2. The clock signal correction device of claim 1, wherein
a phase difference between the first clock signal and the second clock signal is 180 degrees, and a phase difference between the third clock signal and the fourth clock signal is 180 degrees.

3. The clock signal correction device of claim 1, wherein the calibration circuit comprises:
a second clock signal generator configured to generate a first set of monitoring clock signals that synchronize with edges of the first clock signal and the second clock signal, the first set of monitoring clock signals having a plurality of waveforms corresponding to a plurality of codes for adjusting a duty cycle;
a duty cycle monitor configured to output a duty code based on a duty ratio of the first set of monitoring clock signals; and
a calibration logic configured to generate the first skew code.

4. The clock signal correction device of claim 3, wherein the first set of monitoring clock signals comprise:
a first monitoring clock signal that transitions to a first logic state in synchronization with a rising edge of the first clock signal and transitions to a second logic state in synchronization with a rising edge of the second clock signal; and
a second monitoring clock signal that transitions to the second logic state in synchronization with the rising edge of the first clock signal and transitions to the first logic state in synchronization with the rising edge of the second clock signal.

5. The clock signal correction device of claim 4, wherein the first logic state and the second logic state are inverted from each other.

6. The clock signal correction device of claim 4, wherein the duty cycle monitor is configured to:
determine a first duty code based on a duty ratio of the first monitoring clock signal, and determine, as a first code, a value of a code of the plurality of codes in which the first duty code of the first monitoring clock signal changes, and
determine a second duty code based on a duty ratio of the second monitoring clock signal, and determine, as a second code, a value of a code of the plurality of codes in which the second duty code of the second monitoring clock signal changes, and
wherein the calibration logic is configured to determine the first skew code based on the first code and the second code.

7. The clock signal correction device of claim 6, wherein the first skew code includes an intermediate value between the first code and the second code.

8. The clock signal correction device of claim 3, wherein
the second clock signal generator is configured to generate a second set of monitoring clock signals that synchronize with edges of the third clock signal and the fourth clock signal, the second set of monitoring clock signals having a plurality of waveforms corresponding to the plurality of codes,
the duty cycle monitor is configured to determine a third duty code based on a duty ratio of the second set of monitoring clock signals and determine a value of a code of the plurality of codes in which the third duty code of the second set of monitoring clock signals changes, and
the calibration logic is configured to determine the second skew code based on the value of the code.

9. The clock signal correction device of claim 1, wherein the first clock signal generator is an oscillator.

10. The clock signal correction device of claim 1, wherein a phase difference between the plurality of first multi-phase clock signals is 90 degrees.

11. A semiconductor device, comprising:
a memory controller configured to output, in a first mode, a first clock signal of a first frequency and output, in a second mode different from the first mode, a mode signal indicative of the second mode; and
a memory device configured to
generate, using the first clock signal in the first mode, a plurality of first multi-phase clock signals having different phases,
generate, based on the mode signal, a second clock signal of a second frequency,
generate a third clock signal based on a plurality of second multi-phase clock signals that have different phases, the plurality of second multi-phase clock signals being generated using the second clock signal, and
determine, based on a duty cycle of the third clock signal, a value of a skew code for adjusting phases of the plurality of first multi-phase clock signals.

12. The semiconductor device of claim 11, wherein the memory device is configured to:
select clock signals of the plurality of second multi-phase clock signals in the second mode; and
generate the skew code based on the duty cycle of the third clock signal that are generated in synchronization with edges of the selected clock signals, and
wherein a phase difference between the selected clock signals is 180 degrees.

13. The semiconductor device of claim 12, wherein the third clock signal comprises a first monitoring clock signal and a second monitoring clock signal, each of the first and second monitoring clock signals having a plurality of waveforms corresponding to a plurality of codes for adjusting a duty cycle, and each of the first and second monitoring clock signals transitioning to a first logic state or a second logic state in synchronization with a corresponding rising edge of the selected clock signals,
wherein the memory device is configured to:
monitor the duty cycle of the first monitoring clock signal,
determine, as a first code, a code of the plurality of codes in which a duty code changes based on a duty ratio of the first monitoring clock signal,
monitor the duty cycle of the second monitoring clock signal, and
determine, as a second code, a code of the plurality of codes in which a duty code changes based on a duty ratio of the second monitoring clock signal.

14. The semiconductor device of claim 13, wherein the skew code is an intermediate value between the first code and the second code.

15. The semiconductor device of claim 11, wherein the first frequency is equal to the second frequency.

16. The semiconductor device of claim 11, wherein the second mode is an initial driving mode of the semiconductor device.

17. A computing system comprising:
a memory controller configured to transmit a data clock signal and data based on a host request and transmit a mode signal indicating that a computing system has entered a first mode; and
a memory device configured to:
generate a clock signal based on the mode signal,
generate a monitoring clock signal having a logic state that transitions in synchronization with edges of clock signals of a plurality of internal clock signals, the plurality of internal clock signals having different phases and being generated based on the clock signal, and the monitoring clock signal having a plurality of waveforms corresponding to a plurality of codes, the plurality of codes configured to adjust at least one duty cycle of the clock signals of the plurality of internal clock signals,
generate, using the data clock signal, a plurality of multi-phase clock signals having different phases, and
adjust phases of the plurality of multi-phase clock signals using the code that is determined based on a duty ratio of the monitoring clock signal.

18. The computing system of claim 17, wherein the memory controller is configured to transmit the mode signal during a first time interval and transmit the data clock signal during a second time interval, and
wherein the first time interval and the second time interval are separated from each other.

19. The computing system of claim 17, wherein the first mode is an initial operating mode of the computing system.

20. The computing system of claim 17, wherein a phase difference between the clock signals of the plurality of internal clock signals is 180 degrees.
